(19) United States
(12) Patent Application Publication
(10) Pub. No.: US 2025/0372482 A1
(43) Pub. Date: Dec. 4, 2025

(54) THROUGH SEMICONDUCTOR VIA AS A WELL TAP STRUCTURE

(71) Applicant: Intel Corporation, Santa Clara, CA (US)

(72) Inventor: Changyok Park, Portland, OR (US)

(73) Assignee: Intel Corporation, Santa Clara, CA (US)

(21) Appl. No.: 18/678,793

(22) Filed: May 30, 2024

(51) Int. Cl. H01L 23/48

(52) U.S. Cl. CPC H01L 23/481

(57) ABSTRACT

Techniques are provided for forming one or more well taps from through semiconductor via (TSV) structures between backside and frontside conductive layers. The well tap/TSV structures may be formed during the same fabrication process used to form other TSVs and may be located in the same general area of the device layer. The well tap/TSV structures may be nano-scale structures that extend partially or fully through the device layer. One or more first recesses through the device layer include TSVs for routing power or ground between the backside conductive layer beneath the device layer and a frontside conductive layer above the device layer without contacting the device layer. One or more second recesses through the device layer include power tap/TSV structures that can provide frontside to backside routing and that also conductively couple semiconductor material of the device layer to backside power and/or ground terminals or rails.

### BACKGROUND

As integrated circuits continue to scale downward in size, a number of challenges arise. As density of devices increases, the available space on a given die dwindles rapidly. Some structures require a certain amount of space to operate effectively, but the limited available footprint on a die makes arranging these structures challenging. Accordingly, there remain a number of non-trivial challenges with respect to fabricating certain structures in an integrated circuit.

### BRIEF DESCRIPTION OF THE DRAWINGS

FIG. 1 is a cross-sectional view that illustrates an example portion of an integrated circuit configured with an interconnect region over a plurality of semiconductor devices and a well tap connected to a backside interconnect, in accordance with some embodiments of the present disclosure.

FIG. 2 is a cross-sectional view of various through semiconductor vias (TSVs) and well taps coupled to a backside interconnect, in accordance with some embodiments of the present disclosure.

FIGS. 3A-3L illustrate cross-sectional views of a process for forming both TSVs and well taps through a region of a semiconductor device layer, in accordance with some embodiments of the present disclosure.

FIG. 4 illustrates a cross-section view of a chip package containing one or more semiconductor dies, in accordance with some embodiments of the present disclosure.

FIG. 5 is a flowchart of a method for forming both TSVs and well taps through a region of a semiconductor device layer, in accordance with some embodiments of the present disclosure.

FIG. 6 illustrates a computing system including one or more integrated circuits, as variously described herein, in accordance with some embodiments of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming one or more well taps from through semiconductor via (TSV) structures between a backside conductive layer and a frontside conductive layer. The combination well tap/TSV structures may be formed during the same fabrication process used to form other TSV-only structures and may be located in the same general area of the device layer. The combination well tap/TSV structures may be, for example, nano-scale structures that extend through the entire device layer of a die (e.g., less than 1000 nm or less than 500 nm in height), although micro-scale configurations may utilize the techniques as well. In an example, a plurality of recesses are formed through an entire thickness of a given region of a semiconductor device layer. The semiconductor device layer may include any number of transistors in another region of the device layer. One or more first recesses include a dielectric liner along all sidewalls of the first recesses and a conductive fill on the dielectric liner, so as to provide one or more TSV-only structures. One or more second recesses include a conductive layer (e.g., silicide) on the sidewalls of the second recesses and a conductive fill on the conductive layer, so as to provide one or more combination well tap/TSV structures. The top surfaces of the conductive fill in both the first and second recesses may be coupled to any number of frontside conductive layers as part of a frontside interconnect network. The substrate (or a portion thereof) can be removed from the backside, and the exposed bottom surfaces of the conductive fill in both the first and second recesses may be coupled to any number of backside conductive layers as part of a backside interconnect network. The one or more first recesses include TSV-only structures for, for instance, routing signals, power, or ground between the backside conductive layer beneath the device layer and a frontside conductive layer above the device layer without contacting the device layer. The one or more second recesses include combination power tap/TSV structures that can provide power, and/or ground routing as well, but also conductively couple the given region of the device layer to the backside power or ground terminal. The term TSV is often used to refer to through silicon vias, but in the present disclosure is used more broadly to include a via that passes through any semiconductor material, not just silicon. Numerous configurations and variations will be apparent in light of this disclosure.

### General Overview

As previously noted above, it can be challenging to use the space on a given die effectively. Numerous structures beyond the active devices (e.g., transistors) must be arranged on the die as well, including interconnect structures and well tap structures. The well tap structures are used to connect n-doped or p-doped portions of the semiconductor device layer to a power or ground rail to prevent voltage drift and latch-up issues. Multiple TSV structures and separate well tap structures may be necessary on a given die, thus decreasing the footprint available for the active devices.

Techniques are described herein for forming nanoscale TSV structures that also act as well tap structures. The TSV structures include a core conductive material that extends through the entire thickness of a semiconductor device layer and between a backside conductive layer and a topside conductive layer. According to some embodiments, sidewalls of one or more of the TSV structures passing through the device layer include a conductive material layer rather than a dielectric liner. The conductive material layer may include, for instance, a silicide or other low ohmic contact material to conductively couple the conductive core of the TSV to the semiconductor device layer. In some examples, the combination TSV/well tap structure is coupled to an n-doped or p-doped region of the device layer.

According to an embodiment, an integrated circuit includes a plurality of semiconductor devices in a first region of a device layer, a dielectric layer beneath the device layer, and a conductive via in a second region of the device layer and extending through at least a portion of a thickness of the device layer and extending through an entire thickness of the dielectric layer. Also, a conductive layer is beneath the dielectric layer and contacts a portion of the conductive via, and a conductive material layer is between a sidewall of the device layer and the conductive via. The conductive material layer directly contacts the conductive via and directly contacts a semiconductor material in the second region of the device layer.

According to another embodiment, an electronic device includes a chip package having one or more dies. At least one of the one or more dies includes a device layer comprising a plurality of semiconductor devices in a first region of the device layer, a dielectric layer beneath the device layer, and a conductive via in a second region of the device layer and extending through at least a portion of a thickness of the device layer and extending through an entire thickness of the dielectric layer. Also, a conductive layer is beneath the dielectric layer and contacts a portion of the conductive via, and a conductive material layer is between a sidewall of the device layer and the conductive via. The conductive material layer directly contacts the conductive via and directly contacts a semiconductor material in the second region of the device layer.

According to another embodiment, an integrated circuit includes a semiconductor region comprising one or more semiconductor layers, a dielectric layer beneath the semiconductor region, a conductive via extending through an entire thickness of the semiconductor region and extending through an entire thickness of the dielectric layer, a conductive layer beneath the dielectric layer and contacting a portion of the conductive via, and a conductive material layer between a sidewall of the semiconductor region and the conductive via. The conductive material layer directly contacts the conductive via and directly contacts the semiconductor region.

According to another embodiment, a method of forming an integrated circuit includes: forming a recess through a semiconductor region over a semiconductor substrate; forming a dielectric liner on exposed surfaces within the recess; forming a sacrificial fill at a bottom portion of the recess; removing an exposed portion of the dielectric liner above the sacrificial fill; removing the sacrificial fill; forming a conductive material layer on exposed surfaces of the semiconductor region within the recess; forming a conductive fill within the recess and on the conductive material layer; removing at least a portion of the semiconductor substrate; forming a dielectric layer beneath the semiconductor region; and forming a conductive layer beneath the dielectric layer, the conductive layer contacting at least a portion of the conductive fill.

The techniques can be used with any type of planar and non-planar transistors, including finFETs (sometimes called double-gate transistors, or tri-gate transistors), nanowire and nanoribbon transistors (sometimes called gate-all-around transistors), and thin film transistors, to name a few examples. The source and drain regions can be, for example, epitaxial regions that are deposited during an etch-and-replace source/drain forming process, or doped regions of a given substrate. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which power is being supplied by a buried or backside power rail, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of TSVs extending through the device layer and having a conductive material on their sidewalls that electrically couples the conductive core of the TSVs to the semiconductor material of the device layer. In some examples, such tools may indicate that the conductive material is silicide (e.g., including titanium and silicon). Other examples may show a germanide (e.g., including titanium and germanium), or a III-V-ide (e.g., including titanium and gallium arsenide, or tungsten on indium gallium nitride or indium aluminum nitride).

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

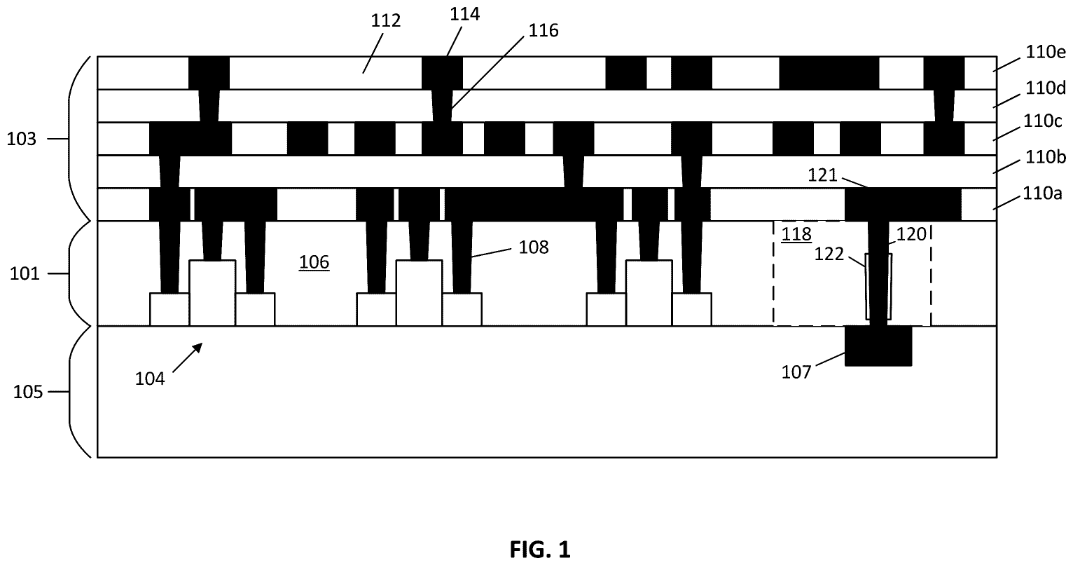

FIG. 1 is a cross-sectional view that illustrates an example portion of an integrated circuit having an interconnect region above a plurality of semiconductor devices, in accordance with an embodiment of the present disclosure. The semiconductor devices in this example are non-planar metal oxide semiconductor (MOS) transistors, such as tri-gate or gate-all-around (GAA) transistors, although other transistor topologies and types can also be used in conjunction with the techniques provided herein, as will be appreciated (e.g., planar transistors, forksheet transistors, thin film transistors, or any other transistors).

According to some embodiments, the integrated circuit includes a device region 101 (sometimes referred to as a device layer), and an interconnect region 103 over the device region 101. Device region 101 may include a plurality of semiconductor devices 104 along with one or more other layers or structures associated with the semiconductor devices 104. For example, device region 101 can also include one or more dielectric layers 106 that surround active portions or contacts of the semiconductor devices 104. Device region 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts may also be a part of, or otherwise include, what is sometimes called a local interconnect, which may be considered part of the device region and usually formed prior to any backend processing. In some examples, device region 101 includes a semiconductor device layer from which the semiconductor channels of the transistors are formed.

As further shown in FIG. 1, device region 101 is over a backside interconnect region 105. In an example, backside processing may be used to remove the substrate from beneath device region 101 and to form any number of backside interconnect layers, that make up interconnect region 105. According to some embodiments, a backside conductive layer 107 may be provided to carry power rail signals or a ground signal (e.g., VDD, VSS, or GND). Any number of backside interconnect layers including dielectric material with patterned conductive traces and vias may be formed.

Interconnect region 103 includes a plurality of interconnect layers 110a-110e stacked over one another. Each interconnect layer can include a dielectric material 112 along with one or more different conductive features. Dielectric material 112 can be any dielectric, such as silicon dioxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conductive via, such as conductive via 116, may extend through an interconnect layer to connect between conductive traces on an upper interconnect layer and a lower interconnect layer. In other cases, a via 116 may only extend part way through a given interconnect layer. Although interconnect region 103 is illustrated with only five interconnect layers, any number of interconnect layers can be used within interconnect region 103. Also, this example shows vias and lines in different interconnect layers, in both single and dual damascene configurations. In other examples, vias and lines may also exist within the same interconnect layer, such as in the case of some dual damascene configurations.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 may include a relatively thin liner or barrier, such as titanium nitride or tantalum nitride.

It should be noted that each of the various conductive vias 116 and conductive contacts 108 are shown with tapered profiles to indicate a more natural appearance due to the etching process used to form the openings. Any degree of tapering may be observed depending on the etch parameters used and the thickness (depth) of the dielectric layer being etched through. Furthermore, conductive vias may be stacked one over the other through different dielectric layers of interconnect region 103. However, in some examples, a single via recess may be formed through more than one dielectric layer yielding a taller, more tapered conductive via that extends through two or more dielectric layers.

The various interconnect layers of interconnect region 103 may not all be the same thickness. According to some embodiments, the interconnect layers increase in thickness moving upwards towards the top of interconnect region 103. Thus, the top-most interconnect layer may have the greatest thickness while the bottom-most interconnect layer may have the smallest thickness. In some examples, the top-most interconnect layer may have a thickness in the range of several micrometers (e.g., 1-4 μm), while the bottom-most interconnect layer may have a thickness of less than 50 nm.

According to some embodiments, semiconductor devices 104 are formed within a first section of device region 101 and a second section 118 of device region 101 includes at least one TSV structure 120. As shown in this example, TSV structure 120 extends through an entire thickness of device region 101 between a frontside conductive layer 121 and backside conductive layer 107. Accordingly, TSV structure 120 provides a conductive connection between frontside conductive layer 121 and backside conductive layer 107. Additionally, TSV structure 120 is electrically coupled to semiconductor material of device region 101. For example, a conductive material layer 122 is provided on or otherwise between semiconductor material sidewalls of device region 101 and the sidewalls of TSV structure 120 to promote an ohmic contact between TSV structure 120 and the semiconductor material of device region 101. The semiconductor material within second section 118 of device region 101 may be, for example, n-doped or p-doped or undoped. Accordingly, TSV structure 120 also acts as a well tap to connect the doped or undoped semiconductor material of device region 101 to power or ground provided by backside conductive layer 107 (or by frontside conductive layer 121).

TSV structure 120 may be any suitable conductive material, such as tungsten, ruthenium, molybdenum, or cobalt. Conductive material layer 122 may be, for example, silicide, germanide, or any other suitable conductive material to enhance the ohmic contact between the semiconductor material of the device layer and a metal or metal alloy.

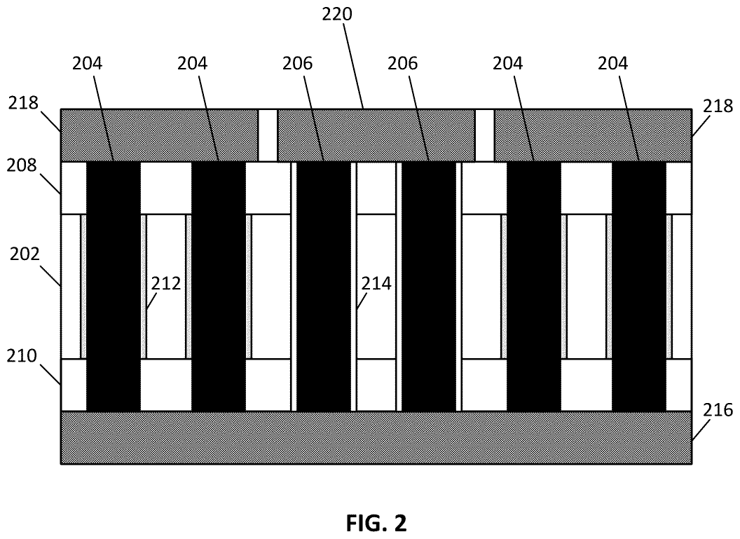

FIG. 2 illustrates a cross-section view through a region of a device layer 202 that includes any number of TSV/tap structures 204 and any number of TSV structures 206 (without conductive contact to device layer 202), according to some embodiments. Each of TSV/tap structures 204 and TSV structures 206 extend through a thickness of device layer 202, which in some examples may include any suitable semiconductor material(s), such as silicon, SiGe, germanium, or any III-V based materials. In this example, device layer 202 may have a total thickness of less than 1000 nm or less than 500 nm, such as between 50 nm and 300 nm. Other regions of device layer 202 may include any number of semiconductor devices, such as planer transistors, thin film transistors (TFTs), trigate transistors, gate-all-around transistors, or forksheet transistors.

TSV/tap structures 204 and TSV structures 206 both include a conductive core that may extend through an entire thickness of at least device layer 202. In some embodiments, the conductive core of TSV/tap structures 204 and TSV structures 206 also extends through a frontside dielectric layer 208 over device layer 202 and a backside dielectric layer 210 beneath device layer 202. Each of frontside dielectric layer 208 and backside dielectric layer 210 may be any suitable dielectric material. In some examples, frontside dielectric layer 208 and backside dielectric layer 210 include any of silicon dioxide, silicon nitride, or silicon oxynitride.

According to some embodiments, the conductive core of TSV/tap structures 204 is conductively coupled to device layer 202 through a conductive material layer 212 formed on the sidewalls of the device layer 202 and/or TSV/tap structures 204. Conductive material layer 212 may be, for example, silicide (for a silicon-based device layer 202) or germanide (for a germanium-based device layer 202) or a III-V-ide (for a III-V semiconductor material based device layer 202), or any other suitable conductive material to enhance the ohmic contact between device layer 202 and TSV/tap structures 204. Conductive material layer 212 may have a lateral thickness, for example, of less than 5 nm, such as between 1 nm and 3 nm. In contrast, TSV structures 206 are electrically isolated from device layer 202 using a dielectric liner 214 on the sidewalls of TSV structures 206. Dielectric liner 214 may be any suitable dielectric material, such as silicon nitride. In some examples, dielectric liner 214 has a different dielectric material compared to at least frontside dielectric layer 208 to provide a measure of etch selectivity between dielectric liner 214 and frontside dielectric layer 208.

According to some embodiments, a backside conductive layer 216 is provided beneath backside dielectric layer 210. Backside conductive layer 216 contacts the bottom surfaces of any number of TSV/tap structures 204 and TSV structures 206. In some examples, backside conductive layer 216 delivers a power rail (e.g., VDD) or ground rail (e.g., VSS) for the circuit. In the illustrated example, TSV/tap structures 204 provide conductive pathways between backside conductive layer 216 and any number of frontside conductive layers 218 that are provided above frontside dielectric layer 208. Similarly, TSV structures 206 provide conductive pathways between backside conductive layer 216 and any number of frontside conductive layers 220 that are provided above frontside dielectric layer 208. TSV/tap structures 204 additionally provide a conductive pathway between backside conductive layer 216 and device layer 202, and between frontside conductive layers 218 and device layer 202, according to some embodiments. It should be understood that the illustrated arrangement of topside conductive layers 218/220, TSV/tap structures 204, and TSV structures 206 is just one example arrangement, and that any arrangement of such elements may be used along device layer 202. In some embodiments, TSV/tap structures 204 extend upwards from backside conductive layer 216 through only a portion of the total height of device layer 202. In such examples, TSV/tap structures 204 act as tap structures to conductively connect device layer 202 with backside conductive layer 216, but do not connect to any frontside conductive layers. Frontside conductive layers 218/220 and backside conductive layer 216 may include any suitable conductive material, such as those previously described above (e.g., copper, tungsten, ruthenium, molybdenum, or cobalt).

### Fabrication Methodology

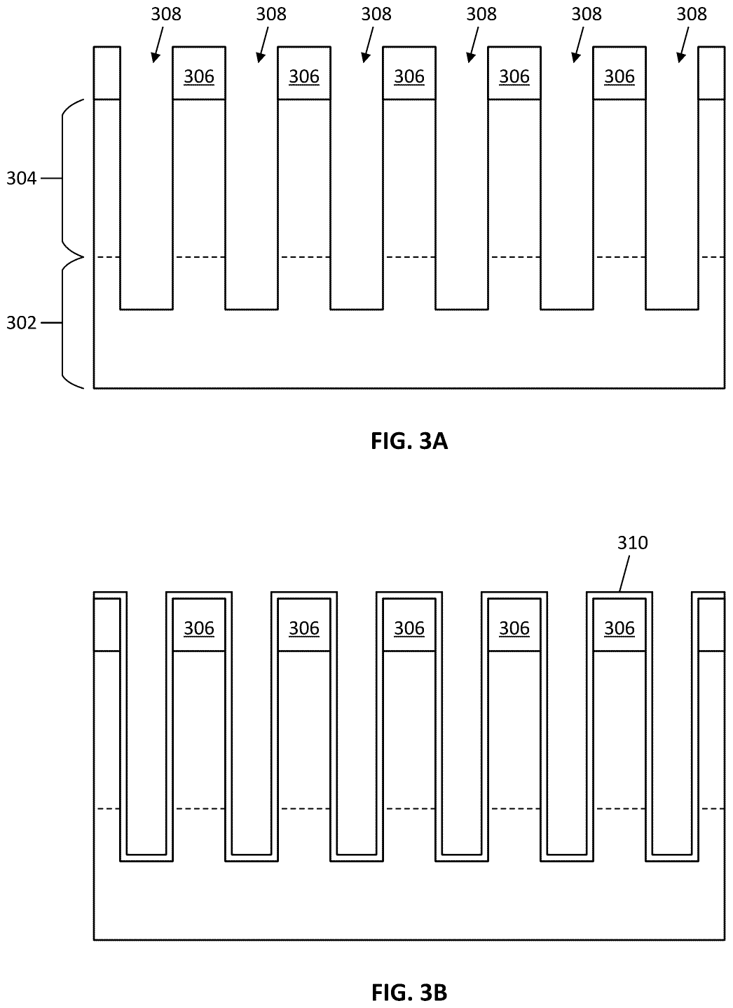

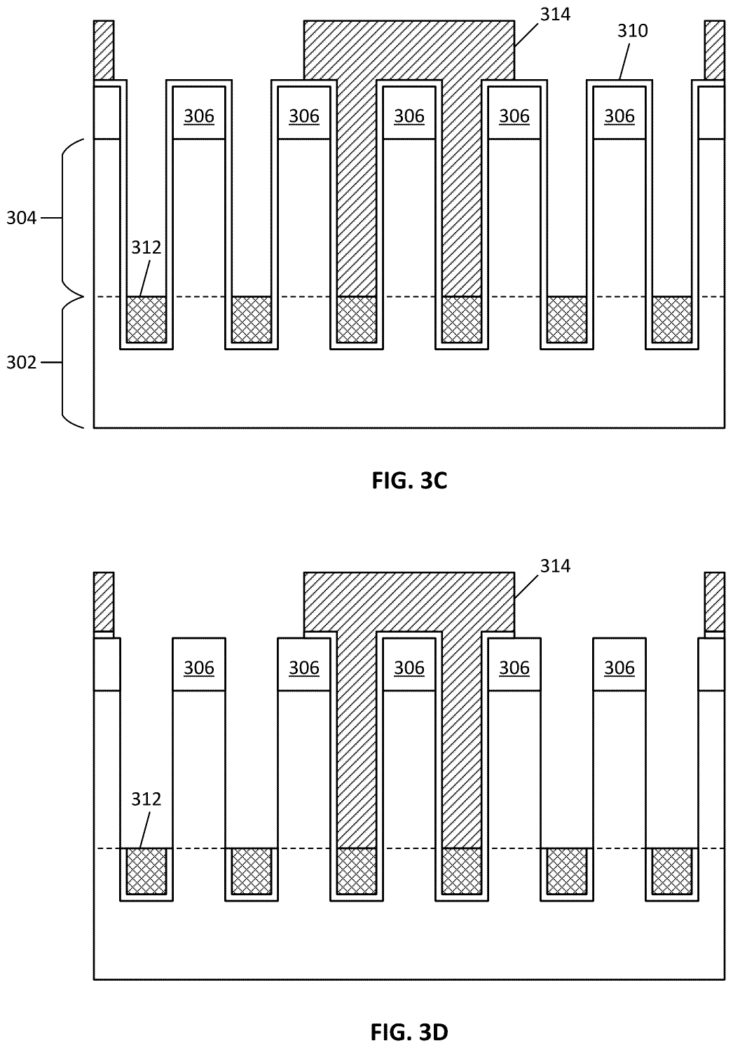

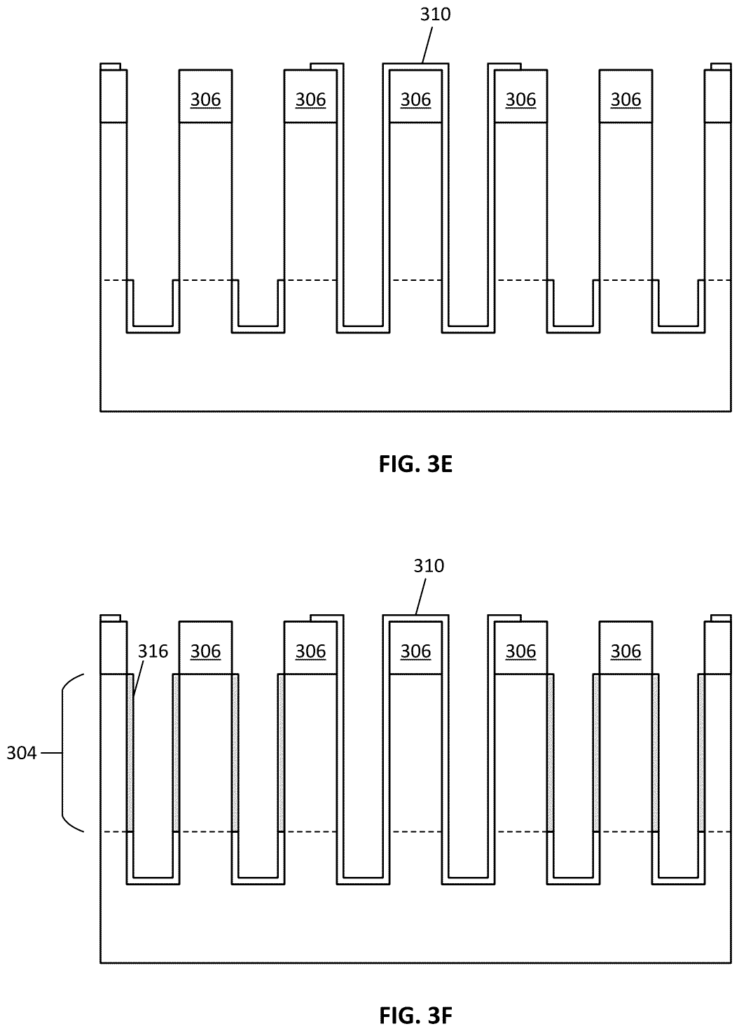

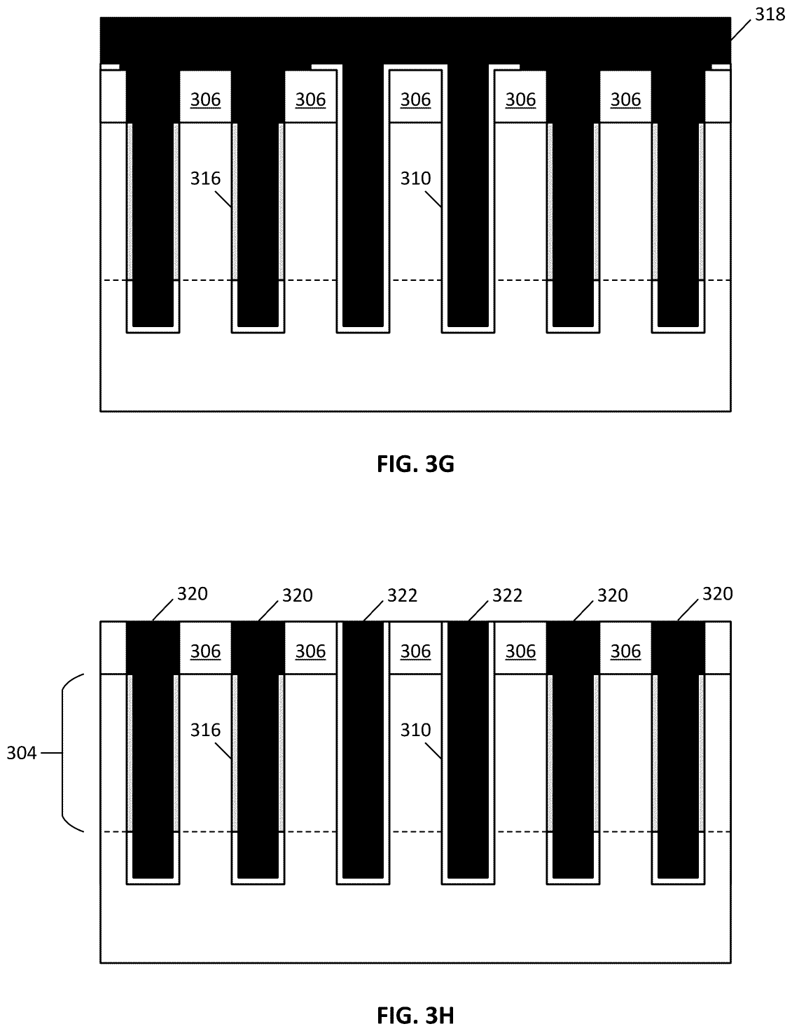

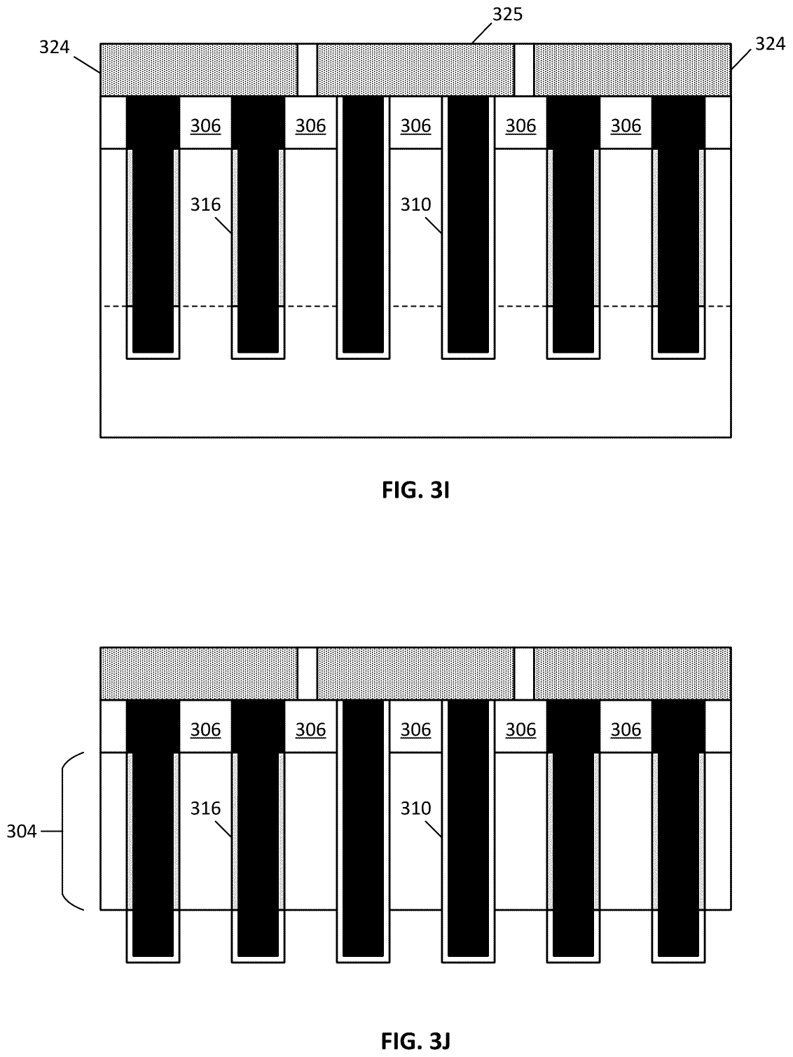

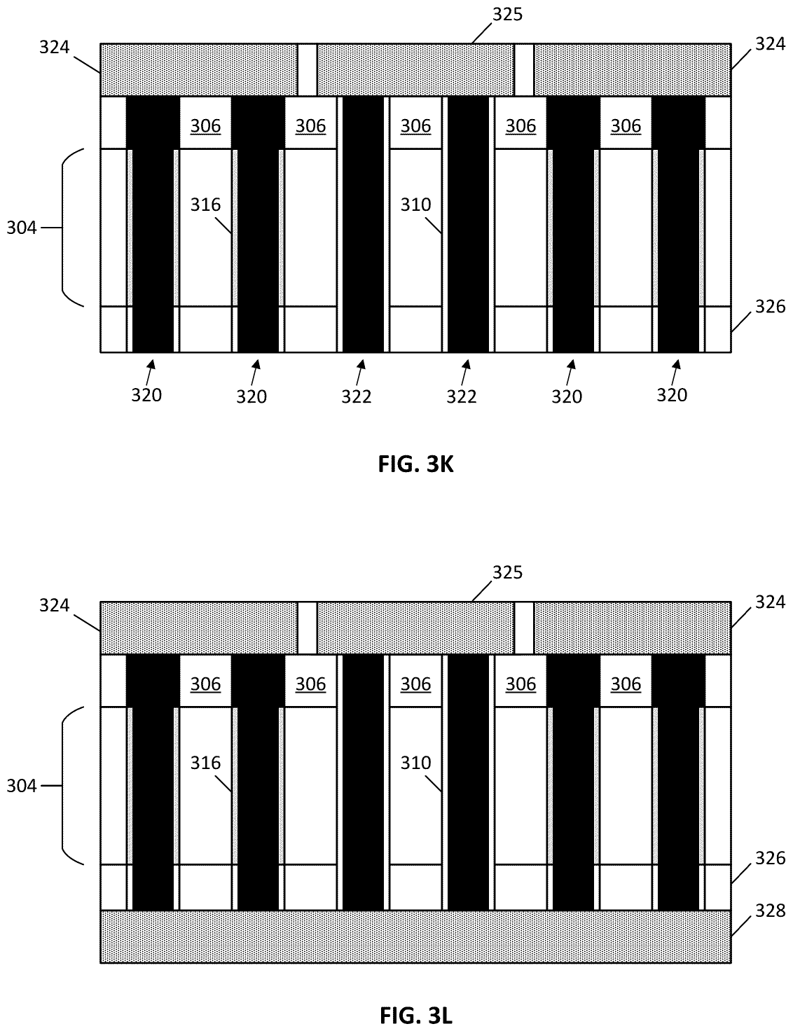

FIGS. 3A-3L are cross-sectional views that collectively illustrate an example process for forming a portion of an integrated circuit, in accordance with an embodiment of the present disclosure. Each figure shows an example structure that results from the process flow up to that point in time, so the depicted structure evolves as the process flow continues, culminating in the structure shown in FIG. 3L, which is similar to the structure illustrated in FIG. 2. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 3A is a cross-sectional view taken through a portion of a substrate 302. Substrate 302 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, a device layer 304 is provided over substrate 302. The illustrated portion of device layer 304 may be away from the semiconductor devices and may include any suitable semiconductor material(s). In one example, device layer 304 includes a single layer of silicon, germanium, or silicon germanium suitable for forming finFET devices. In some examples, device layer 304 includes alternating layers of silicon and silicon germanium suitable for making gate-all-around (GAA) transistors. In still other examples, device layer 304 includes one or more layers of III-V semiconductor materials (e.g., gallium arsenide or indium gallium arsenide) suitable for making amplifiers, filters and power transistors. Although the dimensions can vary from one example to the next, in one example case device layer 304 has a total thickness of less than 500 nm, such as between 30 nm and 150 nm. In some embodiments, device layer 304 includes the same semiconductor material as substrate 302.

According to some embodiments, a frontside dielectric layer 306 is provided on a top surface of device layer 304. Frontside dielectric layer 306 may include any suitable dielectric material, such as silicon dioxide, silicon nitride, silicon carbide, or silicon oxynitride.

According to some embodiments, any number and arrangement of recesses 308 are etched through an entire thickness of frontside dielectric layer 306 and through an entire thickness of device layer 304. A reactive ion etching (RIE) process may be used along with suitable lithography techniques to pattern and etch recesses 308 using frontside dielectric layer 306 as a hard mask material. According to some embodiments, recesses 308 may be trenches that extend into and out of the page, or may have a circular or square plan cross-section shape. According to some embodiments, recesses 308 extend into at least a portion of substrate 302. In FIG. 3A, the boundary between substrate 302 and device layer 304 is indicated by a dashed line, with recesses 308 extending below the dashed line into substrate 302.

FIG. 3B is a cross-sectional view of the structure depicted in FIG. 3A, after the formation of a dielectric liner 310 across the structure, according to some embodiments. Dielectric liner 310 may be any suitable dielectric material, such as silicon dioxide, silicon nitride, or silicon oxynitride. In some examples, dielectric liner 310 has a different material composition compared to frontside dielectric layer 306. Dielectric liner 310 may be conformally deposited along all surfaces of recesses 308 using CVD or ALD, to name a few examples. Dielectric liner 310 may have a thickness, for example, between about 3 nm and about 10 nm.

FIG. 3C is a cross-sectional view of the structure depicted in FIG. 3B, after the formation of sacrificial fill 312 and mask structure 314, according to some embodiments. Sacrificial fill 312 may be any suitable material that can be safely removed at a later time without damaging surrounding structures. In one example, sacrificial fill 312 includes carbon hard mask (CHM). Other suitable materials include titanium nitride or aluminum oxide. According to some embodiments, sacrificial fill 312 is first deposited within all recesses 308 and subsequently recessed using a suitable isotropic etching process to a final height at the bottom of recesses 308. Sacrificial fill 312 may be recessed to a final height such that its top surface is near the boundary between device layer 304 and substrate 302 (as indicated with a dashed line), such as within 10 nm, within 5 nm, or within 2 nm of the boundary.

Following the formation of sacrificial fill 312, mask structure 314 may be deposited across the structure and lithographically patterned to be removed from some recesses while remaining in others. According to some embodiments, any recesses still containing mask structure 314 will ultimately be TSV-only structures and any recesses free of mask structure 314 will ultimately be combination TSV/tap structures. Mask structure 314 may be a photoresist or a suitable hard mask structure that can be safely patterned without damaging dielectric liner 310. In some examples, mask structure 314 and sacrificial fill 312 are the same material (e.g., CHM), which is lithographically patterned and selectively removed to provide the structure in FIG. 3C.

FIG. 3D is a cross-sectional view of the structure depicted in FIG. 3C, after the removal of exposed portions of dielectric liner 310, according to some embodiments. Any portions of dielectric liner 310 not protected by mask structures 312 and 314 may be removed using a suitable isotropic etching process.

FIG. 3E is a cross-sectional view of the structure depicted in FIG. 3D, after the removal of sacrificial fill 312 and mask structure 314. Any suitable isotropic etching processes may be used to remove sacrificial fill 312 and mask structure 314. In some examples, sacrificial fill 312 and mask structure 314 are removed during the same isotropic etching process, such as during the same ashing process.

FIG. 3F is a cross-sectional view of the structure depicted in FIG. 3E following the formation of a conductive material layer 316 on the recess sidewalls where the semiconductor material of device layer 304 is exposed. Conductive material layer 316 may include, for example, silicide (metal+silicon) to provide an enhanced ohmic contact to exposed silicon regions of device layer 304. In another example, conductive material layer 316 may include germanicide (metal+germanium) to provide an enhanced ohmic contact to exposed germanium regions of device layer 304. In another example, conductive material layer 316 may include III-V-ide (metal+III-V material such as gallium arsenide, indium phosphide, or indium gallium arsenide) to provide an enhanced ohmic contact to exposed III-V material regions of device layer 304. The metal may be, for example, titanium, nickel, tungsten, gold, aluminum, or an alloy thereof. Conductive material layer 316 may be formed in various ways. In one example, a layer of titanium is deposited across the entire structure and subsequently annealed in a nitrogen-rich environment. In areas where the titanium is deposited on silicon (e.g., on device layer 304) titanium disilicide (TiSi₂) is formed, while titanium nitride is formed everywhere else. The excess titanium nitride may then be selectively removed using a suitable isotropic etching process leaving behind only the titanium disilicide. In another example, silicide may be epitaxially grown on the exposed silicon surfaces along the sidewalls of recesses 308. The growth process is selective in that silicide growth occurs only on the exposed silicon surfaces, and thus only forms the silicide in those regions, according to some embodiments. Similar selective growth of germanide or III-V-ide may be used with other semiconductor materials. In any such cases, conductive material layer 316 does not form within recesses 308 that still include dielectric liner 310 along the entire sidewall height. Any number of deposition processes can be used to provide conductive material layer 316, such as CVD and ALD, along with thermal annealing to react the touching metal and semiconductor materials. Conductive material layer 316 may be formed to a lateral thickness of, for example, less than 5 nm, such as between 1 nm and 3 nm. Other examples may have a different thickness.

FIG. 3G is a cross-sectional view of the structure depicted in FIG. 3F following the formation of a conductive fill 318 that substantially fills each of recesses 308, according to some embodiments. Conductive fill 318 may be any suitable conductive material, such as copper, tungsten, molybdenum, cobalt, or ruthenium. In some examples, a conductive liner is first conformally deposited (e.g., via CVD or ALD) followed by a conductive fill to substantially fill recesses 308. Conductive fill 318 may be deposited using any one of electroplating, electroless plating, CVD, ALD, or PECVD, to name a few examples.

FIG. 3H is a cross-sectional view of the structure depicted in FIG. 3G following a polishing procedure to remove excess conductive fill 318 from above frontside dielectric layer 306, according to some embodiments. Chemical mechanical polishing (CMP) may be used to remove the excess conductive fill 318 and also to remove any portions of dielectric liner 310 above frontside dielectric layer 306. The polishing process results in TSV/tap structures 320 having conductive material layer 316 on its sidewalls between the conductive fill material and device layer 304, and TSV structures 322 having dielectric liner 310 on its sidewalls between the conductive fill material and device layer 304, according to some embodiments. The polishing process results in the top surfaces of TSV/tap structures 320 and TSV structures 322 being substantially coplanar with a top surface of frontside dielectric layer 306.

FIG. 3I is a cross-sectional view of the structure depicted in FIG. 3H, following the formation of any number of frontside conductive layers 324 and 325, according to some embodiments. Frontside conductive layers 324/325 may be formed though one or more dielectric layers to contact the top surfaces of any number of TSV/tap structures 320 or TSV structures 322. In the illustrated example, frontside conductive layers 324 contact the top surfaces of TSV/tap structures 320 and frontside conductive layer 325 contacts the top surfaces of TSV structures 322. Frontside conductive layers 324/325 may be part of a frontside interconnect network including any number of interconnect layers for routing signal and power across the circuit. Frontside conductive layers 324/325 may include any suitable conductive material, such as copper, tungsten, molybdenum, cobalt, or ruthenium.

FIG. 3J is a cross-sectional view of the structure depicted in FIG. 3I, following the removal of a backside portion of substrate 302, according to some embodiments. The backside of substrate 302 may be removed using any number of or combination of techniques such as dry etching, wet etching, polishing, or grinding. In some examples, the backside of substrate 302 is polished or grinded down until the lower surface of conductive fill 318 (or dielectric liner 310) is exposed. Further recessing of substrate 302 (which may reveal a lower surface of device layer 304) may then be performed using any suitable etching process such that the bottom ends of TSV/tap structures 320 and TSV structures 322 protrude out from the lower surface of device layer 304.

FIG. 3K is a cross-sectional view of the structure depicted in FIG. 3J, following the formation of a backside dielectric layer 326, according to some embodiments. Backside dielectric layer 326 may be formed on the bottom surface of device layer 304 and around the ends of TSV/tap structures 320 and TSV structures 322. Backside dielectric layer 326 may be any suitable dielectric material, such as silicon dioxide, silicon nitride, or silicon oxynitride. According to some embodiments, a bottom surface of backside dielectric layer 326 may be polished until it is substantially coplanar with a bottom surface of conductive fill 318 within TSV/tap structures 320 and TSV structures 322.

FIG. 3L is a cross-sectional view of the structure depicted in FIG. 3K, following the formation of a backside conductive layer 328 beneath backside dielectric layer 326, according to some embodiments. Backside conductive layer 328 may be part of a backside interconnect structure made up of any number of backside interconnect layers. Backside conductive layer 328 may contact the exposed bottom surface of conductive fill 318 within TSV/tap structures 320 and TSV structures 322. In some examples, more than one backside conductive layer is patterned to make contact with any number of TSV/tap structures 320 and/or TSV structures 322. In the illustrated example, backside conductive layer 328 extends to contact the bottom surface of each TSV/tap structure 320 and TSV structure 322. Backside conductive layer 328 may include any suitable conductive material, such as copper, tungsten, ruthenium, molybdenum, or cobalt. Backside conductive layer 328 may be arranged to deliver rail power or ground to the circuit.

In the illustrated example, TSV structures 322 provide a conductive pathway between backside conductive layer 328 and frontside conductive layer 325. TSV/tap structures 320 provide conductive pathways between backside conductive layer 328 and frontside conductive layers 324. Additionally, TSV/tap structures 320 provide a conductive pathway between backside conductive layer 328 and device layer 304, according to some embodiments.

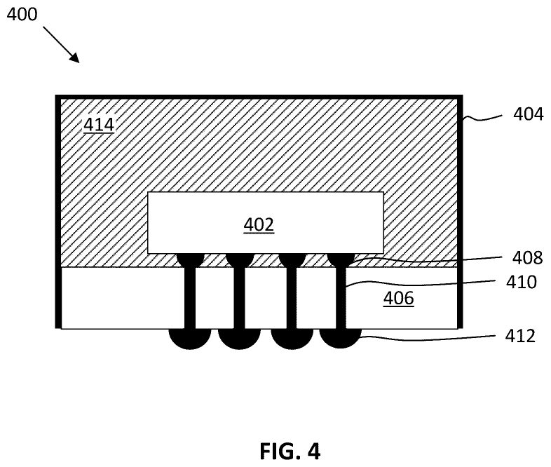

FIG. 4 illustrates an example embodiment of a chip package 400, in accordance with an embodiment of the present disclosure. As can be seen, chip package 400 includes one or more dies 402. One or more dies 402 may include at least one integrated circuit having a structure as described in any of the aforementioned embodiments. One or more dies 402 may include any other circuitry used to interface with other devices formed on the dies, or other devices connected to chip package 400, in some example configurations.

As can be further seen, chip package 400 includes a housing 404 that is bonded to a package substrate 406. The housing 404 may be any standard or proprietary housing, and may provide, for example, electromagnetic shielding and environmental protection for the components of chip package 400. The one or more dies 402 may be conductively coupled to a package substrate 406 using connections 408, which may be implemented with any number of standard or proprietary connection mechanisms, such as solder bumps, ball grid array (BGA), pins, or wire bonds, to name a few examples. Package substrate 406 may be any standard or proprietary package substrate, but in some cases includes a dielectric material having conductive pathways (e.g., including conductive vias and lines) extending through the dielectric material between the faces of package substrate 406, or between different locations on each face. In some embodiments, package substrate 406 may have a thickness less than 1 millimeter (e.g., between 0.1 millimeters and 0.5 millimeters), although any number of package geometries can be used. Additional conductive contacts 412 may be disposed at an opposite face of package substrate 406 for conductively contacting, for instance, a printed circuit board (PCB). One or more vias 410 extend through a thickness of package substrate 406 to provide conductive pathways between one or more of connections 408 to one or more of contacts 412. Vias 410 are illustrated as single straight columns through package substrate 406 for ease of illustration, although other configurations can be used (e.g., damascene, dual damascene, through-silicon via, or an interconnect structure that meanders through the thickness of substrate 406 to contact one or more intermediate locations therein). In still other embodiments, vias 410 are fabricated by multiple smaller stacked vias, or are staggered at different locations across package substrate 406. In the illustrated embodiment, contacts 412 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 412, to inhibit shorting.

In some embodiments, a mold material 414 may be disposed around the one or more dies 402 included within housing 404 (e.g., between dies 402 and package substrate 406 as an underfill material, as well as between dies 402 and housing 404 as an overfill material). Although the dimensions and qualities of the mold material 414 can vary from one embodiment to the next, in some embodiments, a thickness of mold material 414 is less than 1 millimeter. Example materials that may be used for mold material 414 include epoxy mold materials, as suitable. In some cases, the mold material 414 is thermally conductive, in addition to being electrically insulating.

### Methodology

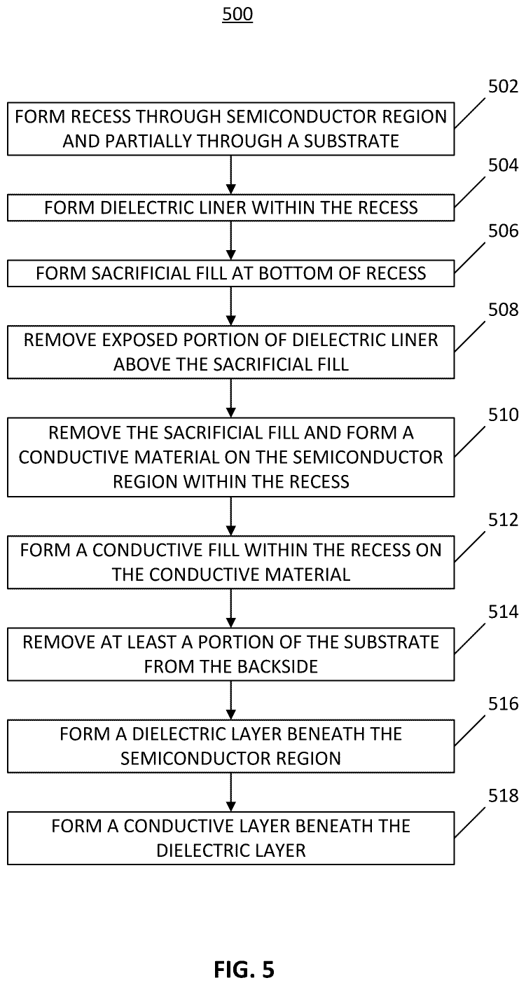

FIG. 5 is a flow chart of a method 500 for forming at least a portion of an integrated circuit, according to an embodiment. Various operations of method 500 may be illustrated in FIGS. 3A-3L. However, the correlation of the various operations of method 500 to the specific components illustrated in the aforementioned figures is not intended to imply any structural and/or use limitations. Rather, the aforementioned figures provide one example embodiment of method 500. Other operations may be performed before, during, or after any of the operations of method 500. Some of the operations of method 500 may be performed in a different order than the illustrated order.

Method 500 begins with operation 502 where a recess is formed through a semiconductor region and partially through a substrate beneath the semiconductor region. A RIE process may be used along with suitable lithography techniques to pattern and etch the recess. In some embodiments, a frontside dielectric layer over the semiconductor region is used as a hard mask material to pattern the location of the recess. According to some embodiments, the recess may have an elongated trench shape, or may have a circular or square plan cross-section shape.

Method 500 continues with operation 504 where a dielectric liner is formed within the recess. The dielectric liner may be any suitable dielectric material, such as silicon dioxide, silicon nitride, or silicon oxynitride. In some examples, the dielectric liner has a different material composition compared to the frontside dielectric layer. The dielectric liner may be conformally deposited along all surfaces of the recesses using CVD or ALD to a thickness, for example, between about 3 nm and about 10 nm.

Method 500 continues with operation 506 where a sacrificial fill is formed at the bottom of the recess. The sacrificial fill may be any suitable material that can be safely removed at a later time without damaging surrounding structures. For example, the sacrificial fill may include CHM, titanium nitride, or aluminum oxide to name a few examples. According to some embodiments, the sacrificial fill is first deposited within the recess and subsequently recessed using a suitable isotropic etching process to a final height at the bottom of the recesses. The sacrificial fill may be recessed to a final height such that its top surface is near the boundary between the semiconductor region and the substrate, such as within 10 nm, within 5 nm, or within 2 nm of the boundary, according to some example embodiments.

Method 500 continues with operation 508 where exposed portions of the dielectric liner not protected by the sacrificial fill are removed from within the recess. The dielectric liner may be removed using any suitable isotropic etching process. The removal of the dielectric liner exposes the semiconductor region along the sidewalls of the recess, according to some embodiments.

Method 500 continues with operation 510 where the sacrificial fill is removed and a conductive material layer is formed on the exposed semiconductor region within the recess. The sacrificial material may be removed using any suitable isotropic etching process. The conductive material layer may be, for example, a silicide, a germanide, a III-V-ide, or other suitable conductive material to enhance the ohmic contact to the semiconductor region.

In one example, a layer of titanium is deposited across the entire structure and subsequently annealed. In areas where the titanium is deposited on the semiconductor region, titanium disilicide (in examples where the semiconductor region includes silicon) is formed, while titanium nitride is formed everywhere else. The excess titanium nitride may then be selectively removed using a suitable isotropic etching process leaving behind only the silicide on the sidewalls of the recess. In another example, silicide may be epitaxially grown on the exposed portions of the semiconductor region along the sidewalls of the recesses. The growth process occurs only on the exposed silicon surfaces, and thus only forms the silicide in those regions, according to some embodiments. In another example, germanide may be epitaxially grown on the exposed portions of the semiconductor region along the sidewalls of the recesses. The growth process occurs only on the exposed germanium surfaces, and thus only forms the germanide in those regions, according to some embodiments. In still another example, III-V-ide may be epitaxially grown on the exposed portions of the semiconductor region along the sidewalls of the recesses. The growth process occurs only on the exposed III-V semiconductor material surfaces, and thus only forms the III-V-ide in those regions, according to some embodiments. The conductive material layer may be formed to a lateral thickness, for example, of less than 5 nm, such as between 1 nm and 3 nm.

Method 500 continues with operation 512 where a conductive fill is formed within the recess and on the conductive material layer. The conductive fill may be any suitable conductive material, such as copper, tungsten, molybdenum, cobalt, or ruthenium. The conductive fill may be deposited using any one of electroplating, electroless plating, CVD, ALD, or PECVD, to name a few examples. As noted above, a conductive liner may first be deposited on the exposed surfaces of the recess followed by a conductive fill on the conductive liner.

Method 500 continues with operation 514 where at least a portion of the substrate is removed from the backside. The backside of the substrate may be removed using any number of or combination of techniques such as dry etching, wet etching, polishing, or grinding. In some examples, the backside of the substrate is polished or grinded down until the lower surface of the conductive fill is exposed. Further recessing of the substrate may then be performed around the end of the conductive fill (which may reveal a lower surface of the semiconductor region).

Method 500 continues with operation 516 where a backside dielectric layer is formed beneath the semiconductor region. According to some embodiments, the backside dielectric layer is also formed around the lower end of the conductive fill that extends out from beneath the semiconductor region. The backside dielectric layer may be any suitable dielectric material, such as silicon dioxide, silicon nitride, or silicon oxynitride. According to some embodiments, a bottom surface of the backside dielectric layer may be polished until it is substantially coplanar with a bottom surface of the conductive fill.

Method 500 continues with operation 518 where a backside conductive layer is formed beneath the backside dielectric layer. According to some embodiments, the backside conductive layer contacts a bottom surface of the conductive fill. The backside conductive layer may be part of a backside interconnect structure made up of any number of backside interconnect layers. The backside conductive layer may include any suitable conductive material, such as copper, tungsten, ruthenium, molybdenum, or cobalt. In some embodiments, the backside conductive layer is be arranged to deliver rail power or ground to the circuit.

It should be noted that the conductive fill provides a well tap structure to couple between the semiconductor region and the backside conductive layer. A frontside conductive layer may also be formed above the conductive fill, such that it also acts as a TSV between the frontside conductive layer and the backside conductive layer.

### Example System

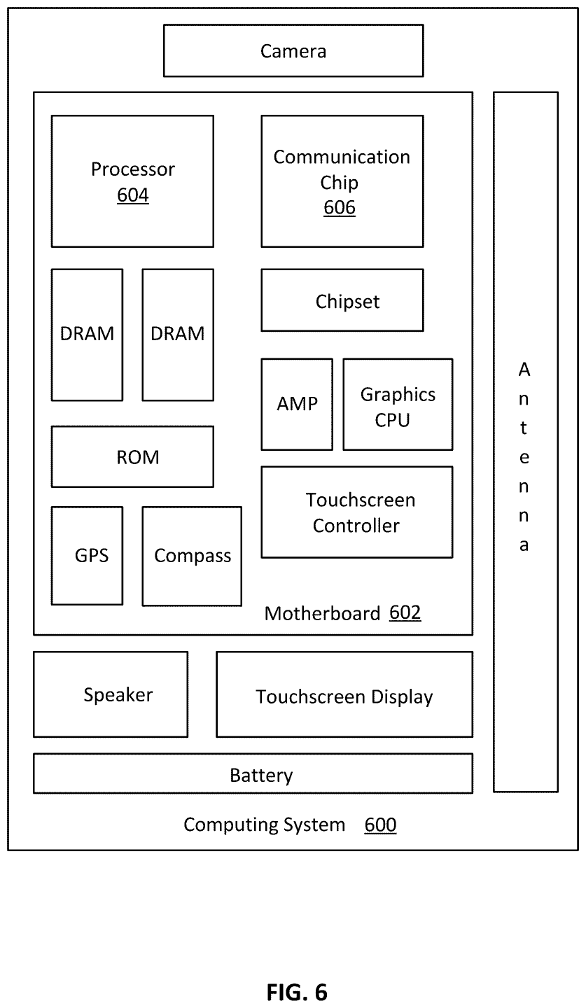

FIG. 6 is an example computing system implemented with one or more of the integrated circuit structures as disclosed herein, in accordance with some embodiments of the present disclosure. As can be seen, the computing system 600 houses a motherboard 602. The motherboard 602 may include a number of components, including, but not limited to, a processor 604 and at least one communication chip 606, each of which can be physically and electrically coupled to the motherboard 602, or otherwise integrated therein. As will be appreciated, the motherboard 602 may be, for example, any printed circuit board (PCB), whether a main board, a daughterboard mounted on a main board, or the only board of system 600, etc.

Depending on its applications, computing system 600 may include one or more other components that may or may not be physically and electrically coupled to the motherboard 602. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 600 may include one or more integrated circuit structures or devices configured in accordance with any of the embodiments disclosed herein (e.g., a module including an integrated circuit having through semiconductor vias (TSVs) and well taps coupled to a backside interconnect). In some embodiments, multiple functions can be integrated into one or more chips (e.g., for instance, note that the communication chip 606 can be part of or otherwise integrated into the processor 604).

The communication chip 606 enables wireless communications for the transfer of data to and from the computing system 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing system 600 includes an integrated circuit die packaged within the processor 604. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 606 also may include an integrated circuit die packaged within the communication chip 606. In accordance with some such example embodiments, the integrated circuit die of the communication chip includes one or more semiconductor devices as variously described herein. As will be appreciated in light of this disclosure, note that multi-standard wireless capability may be integrated directly into the processor 604 (e.g., where functionality of any chips 606 is integrated into processor 604, rather than having separate communication chips). Further note that processor 604 may be a chip set having such wireless capability. In short, any number of processor 604 and/or communication chips 606 can be used. Likewise, any one chip or chip set can have multiple functions integrated therein.

In various implementations, the computing system 600 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 600 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.

Example 1 is an integrated circuit that includes a device layer having a plurality of semiconductor devices in a first region of the device layer and having semiconductor material in a second region of the device layer, a dielectric layer beneath the device layer, a conductive via in the second region of the device layer and extending through at least a portion of a thickness of the device layer and extending through an entire thickness of the dielectric layer, a conductive layer beneath the dielectric layer and contacting a portion of the conductive via, and a conductive material layer between a sidewall of the conductive via and a sidewall of the semiconductor material in the second region of the device layer. The conductive material layer directly contacts the conductive via and directly contacts the semiconductor material in the second region of the device layer.

Example 2 includes the integrated circuit of Example 1, wherein the conductive material layer comprises silicon and titanium.

Example 3 includes the integrated circuit of Example 1, wherein the conductive material layer comprises germanium and titanium.

Example 4 includes the integrated circuit of Example 1, wherein the conductive material layer comprises silicon and a metal.

Example 5 includes the integrated circuit of Example 1, wherein the conductive material layer comprises germanium and metal.

Example 6 includes the integrated circuit of Example 1, wherein the conductive material layer comprises a group III-V semiconductor material and a metal.

Example 7 includes the integrated circuit of any one of Examples 1-6, wherein the conductive material layer has a lateral thickness between about 2 nm and about 5 nm.

Example 8 includes the integrated circuit of any one of Examples 1-7, wherein the conductive via comprises tungsten, molybdenum, cobalt, or ruthenium.

Example 9 includes the integrated circuit of any one of Examples 1-8, wherein the dielectric layer is a first dielectric layer and the conductive layer is a first conductive layer. The integrated circuit further includes a second dielectric layer over the device layer and a second conductive layer over the second dielectric layer. The conductive via contacts a portion of the second conductive layer.

Example 10 includes the integrated circuit of Example 9, wherein the conductive via extends through an entire thickness of the device layer and an entire thickness of the second dielectric layer.

Example 11 includes the integrated circuit of any one of Examples 1-10, wherein the conductive via extends through an entire thickness of the device layer.

Example 12 includes the integrated circuit of any one of Examples 1-11, wherein the conductive material layer extends along the sidewall only between the conductive via and the semiconductor material.

Example 13 includes the integrated circuit of any one of Examples 1-12, wherein the semiconductor material comprises silicon, germanium, silicon and germanium, or a group III-V semiconductor material.

Example 14 includes the integrated circuit of any one of Examples 1-13, wherein a bottom surface of the conductive via is substantially coplanar with a bottom surface of the dielectric layer.

Example 15 is a printed circuit board that includes the integrated circuit of any one of Examples 1-14.

Example 16 is an electronic device that includes a chip package having one or more dies. At least one of the one or more dies includes a device layer comprising a plurality of semiconductor devices in a first region of the device layer, a dielectric layer beneath the device layer, a conductive via in a second region of the device layer and extending through at least a portion of a thickness of the device layer and extending through an entire thickness of the dielectric layer, a conductive layer beneath the dielectric layer and contacting a portion of the conductive via, and a conductive material layer on a sidewall of the conductive via. The conductive material layer directly contacts the conductive via and directly contacts a semiconductor material in the second region of the device layer.

Example 17 includes the electronic device of Example 16, wherein the conductive material layer comprises silicon and titanium.

Example 18 includes the electronic device of Example 16 or 17, wherein the conductive material layer has a lateral thickness between about 2 nm and about 5 nm.

Example 19 includes the electronic device of any one of Examples 16-18, wherein the conductive via comprises tungsten, molybdenum, cobalt, or ruthenium.

Example 20 includes the electronic device of any one of Examples 16-19, wherein the dielectric layer is a first dielectric layer and the conductive layer is a first conductive layer. The at least one of the one or more dies further includes a second dielectric layer over the device layer, and a second conductive layer over the second dielectric layer. The conductive via contacts a portion of the second conductive layer.

Example 21 includes the electronic device of Example 20, wherein the conductive via extends through an entire thickness of the second dielectric layer.

Example 22 includes the electronic device of any one of Examples 16-21, wherein the conductive via extends through an entire thickness of the device layer.

Example 23 includes the electronic device of any one of Examples 16-22, wherein the conductive material layer extends along the sidewall only between the conductive via and the semiconductor material.

Example 24 includes the electronic device of any one of Examples 16-23, wherein the semiconductor material comprises silicon.

Example 25 includes the electronic device of any one of Examples 16-24, wherein a bottom surface of the conductive via is substantially coplanar with a bottom surface of the dielectric layer.

Example 26 includes the electronic device of any one of Examples 16-25, further comprising a printed circuit board, wherein the chip package is attached to the printed circuit board.

Example 27 is a method of forming an integrated circuit. The method includes: forming a recess through a semiconductor region over a semiconductor substrate; forming a dielectric liner on exposed surfaces within the recess; forming a sacrificial fill at a bottom portion of the recess; removing an exposed portion of the dielectric liner above the sacrificial fill; removing the sacrificial fill; forming a conductive material layer on exposed surfaces of the semiconductor region within the recess; forming a conductive fill within the recess and on the conductive material layer; removing at least a portion of the semiconductor substrate; forming a dielectric layer beneath the semiconductor region; and forming a conductive layer beneath the dielectric layer, the conductive layer contacting at least a portion of the conductive fill.

Example 28 includes the method of Example 27, wherein forming the conductive material layer comprises forming a layer comprising silicon and titanium.

Example 29 includes the method of Example 28, wherein forming the conductive material layer comprises: depositing a layer comprising titanium over exposed surfaces within the recess; and annealing the layer comprising titanium to form the conductive material layer on the exposed surfaces of the semiconductor region.

Example 30 includes the method of any one of Examples 27-29, wherein forming the dielectric layer comprises forming the dielectric layer around a bottom end of the conductive fill, and polishing the dielectric layer to expose a bottom surface of the conductive fill.

Example 31 is an integrated circuit that includes a semiconductor region comprising one or more semiconductor layers, a dielectric layer beneath the semiconductor region, a conductive via extending through an entire thickness of the semiconductor region and extending through an entire thickness of the dielectric layer, a conductive layer beneath the dielectric layer and contacting a portion of the conductive via, and a conductive material layer directly contacting the conductive via and directly contacting the semiconductor region.

Example 32 includes the integrated circuit of Example 31, wherein the conductive material layer comprises silicon and titanium.

Example 33 includes the integrated circuit of Example 31, wherein the conductive material layer comprises germanium and titanium.

Example 34 includes the integrated circuit of Example 31, wherein the conductive material layer comprises silicon and a metal.

Example 35 includes the integrated circuit of Example 31, wherein the conductive material layer comprises germanium and metal.

Example 36 includes the integrated circuit of Example 31, wherein the conductive material layer comprises a group III-V semiconductor material and a metal.

Example 37 includes the integrated circuit of any one of Examples 31-36, wherein the conductive material layer has a lateral thickness between about 2 nm and about 5 nm.

Example 38 includes the integrated circuit of any one of Examples 31-37, wherein the conductive via comprises tungsten, molybdenum, cobalt, or ruthenium.

Example 39 includes the integrated circuit of any one of Examples 31-38, wherein the dielectric layer is a first dielectric layer and the conductive layer is a first conductive layer. The integrated circuit further includes a second dielectric layer over the semiconductor region, and a second conductive layer over the second dielectric layer. The conductive via contacts a portion of the second conductive layer.

Example 40 includes the integrated circuit of Example 39, wherein the conductive via extends through an entire thickness of the second dielectric layer.

Example 41 includes the integrated circuit of any one of Examples 31-40, wherein the thickness of the semiconductor region is between about 50 nm and about 200 nm.

Example 42 includes the integrated circuit of any one of Examples 31-41, wherein the conductive material layer extends along the sidewall only between the conductive via and the semiconductor region.

Example 43 includes the integrated circuit of any one of Examples 31-42, wherein the semiconductor region comprises silicon, germanium, silicon and germanium, or a group III-V semiconductor material.

Example 44 includes the integrated circuit of any one of Examples 31-43, wherein a bottom surface of the conductive via is substantially coplanar with a bottom surface of the dielectric layer.

Example 45 is a printed circuit board that includes the integrated circuit of any one of Examples 31-44.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a device layer including a plurality of semiconductor devices in a first region of the device layer, and semiconductor material in a second region of the device layer;
a dielectric layer beneath the device layer;
a conductive via in the second region of the device layer and extending through at least a portion of a thickness of the device layer and extending through an entire thickness of the dielectric layer;
a conductive layer beneath the dielectric layer and contacting a portion of the conductive via; and
a conductive material layer between a sidewall of the conductive via and a sidewall of the semiconductor material in the second region of the device layer, such that the conductive material layer directly contacts the conductive via and directly contacts the semiconductor material in the second region of the device layer.

2. The integrated circuit of claim 1, wherein the conductive material layer comprises silicon and titanium, or comprises germanium and titanium.

3. The integrated circuit of claim 1, wherein the conductive material layer has a lateral thickness between about 2 nm and about 5 nm.

4. The integrated circuit of claim 1, wherein the dielectric layer is a first dielectric layer and the conductive layer is a first conductive layer, the integrated circuit further comprising:
a second dielectric layer over the device layer; and
a second conductive layer over the second dielectric layer;
wherein the conductive via contacts a portion of the second conductive layer.

5. The integrated circuit of claim 4, wherein the conductive via extends through an entire thickness of the device layer and an entire thickness of the second dielectric layer.

6. The integrated circuit of claim 1, wherein the conductive via extends through an entire thickness of the device layer.

7. The integrated circuit of claim 1, wherein the conductive material layer extends along the sidewall only between the conductive via and the semiconductor material.

8. A printed circuit board comprising the integrated circuit of claim 1.

9. An electronic device, comprising:
a chip package comprising one or more dies, at least one of the one or more dies comprising
a device layer comprising a plurality of semiconductor devices in a first region of the device layer;
a dielectric layer beneath the device layer;
a conductive via in a second region of the device layer and extending through at least a portion of a thickness of the device layer and extending through an entire thickness of the dielectric layer;
a conductive layer beneath the dielectric layer and contacting a portion of the conductive via; and
a conductive material layer on a sidewall of the conductive via, such that the conductive material layer directly contacts the conductive via and directly contacts a semiconductor material in the second region of the device layer.

10. The electronic device of claim 9, wherein the conductive material layer comprises silicon and titanium.

11. The electronic device of claim 9, wherein the conductive material layer has a lateral thickness between about 2 nm and about 5 nm.

12. The electronic device of claim 9, wherein the dielectric layer is a first dielectric layer and the conductive layer is a first conductive layer, the at least one of the one or more dies further comprising:
a second dielectric layer over the device layer; and
a second conductive layer over the second dielectric layer,
wherein the conductive via contacts a portion of the second conductive layer.

13. The electronic device of claim 9, wherein the conductive via extends through an entire thickness of the device layer.

14. The electronic device of claim 9, wherein the conductive material layer extends along the sidewall only between the conductive via and the semiconductor material.

15. An integrated circuit, comprising:
a semiconductor region comprising one or more semiconductor layers;
a dielectric layer beneath the semiconductor region;
a conductive via extending through an entire thickness of the semiconductor region and extending through an entire thickness of the dielectric layer;
a conductive layer beneath the dielectric layer and contacting a portion of the conductive via; and
a conductive material layer directly contacting the conductive via and directly contacting the semiconductor region.

16. The integrated circuit of claim 15, wherein the conductive material layer comprises silicon and titanium, or comprises germanium and titanium.

17. The integrated circuit of claim 15, wherein the dielectric layer is a first dielectric layer and the conductive layer is a first conductive layer, the integrated circuit further comprising:
a second dielectric layer over the semiconductor region; and
a second conductive layer over the second dielectric layer,
wherein the conductive via contacts a portion of the second conductive layer.

18. The integrated circuit of claim 17, wherein the conductive via extends through an entire thickness of the second dielectric layer.

19. The integrated circuit of claim 15, wherein the thickness of the semiconductor region is between about 50 nm and about 200 nm.

20. The integrated circuit of claim 15, wherein the conductive material layer extends along the sidewall only between the conductive via and the semiconductor region.
